(19) United States
(12) Patent Application Publication
(10) Pub. No.: US 2004/0195622 A1
(43) Pub. Date: Oct. 7, 2004

(54) Semiconductor structure with silicon on insulator

(75) Inventors: Jiunn-Ren Hwang, Hsin-Chu City (TW); Wei-Tsun Shiau, Kaohsiung (TW)

Correspondence Address: ARENT FOX KINTNER PLOTKIN & KAHN, PLLC, Suite 400, 1050 Connecticut Avenue, N.W., Washington, DC, 20036-5339, US

(73) Assignee: UNITED MICROELECTRONICS CORP.

(21) Appl. No.: 10/407,256

(22) Filed: Apr. 7, 2003

(51) Int. Cl. H01L 27/01; H01L 27/12; H01L 31/0392

(52) U.S. Cl. 257/347

(57) ABSTRACT

A semiconductor structure with silicon on insulator is disclosed in this present invention. The semiconductor structure at least comprises a first substrate and a second substrate. The crystal direction of the first substrate is in a first direction favorable for dicing the semiconductor structure into chips, and the crystal direction of the second substrate is in a second crystal direction favorable to the electron carrier mobility. Hence, this invention can efficiently improve the yield of the semiconductor device by reducing the fracture during dicing. Additionally, this invention can improve the performance of the semiconductor device by raising the electron mobility in the substrate.

### BACKGROUND OF THE INVENTION

1. Field of the Invention

This present invention relates to a semiconductor structure, and more particularly, to a semiconductor structure with silicon on insulator (SOI).

2. Description of the Prior Art

In recent years, with the development of the semiconductor manufacture technology, the integration of the semiconductor device is increasing, and the semiconductor element is continuously scaling down. With the above-mentioned development, many new defects are found and have to be overcome.

For example, as the shrinking of metal oxide semiconductor field effect transistor (MOSFET), the channel length of gate is scaling down for higher driving current. The shorter channel of device also causes a higher leakage current. Therefore, new substrates and/or structures, such as silicon on insulator (SOI) and double-gate device, are adapted to improve the performance of the short channel device.

According to the study in the prior art, the mobility of electron is related to the crystal direction of the wafer. When the crystal direction is in one plane azimuth favorable to the migration of electron, the mobility of electrons in a semiconductor device will be increased. However, the above-mentioned crystal direction of the wafer is not suitable to the orientation of dicing the wafer into chips. The semiconductor devices on the above-mentioned wafer usually get damage or fracture during dicing, and thus the yield of the semiconductor device is decreased. Particularly, with the scaling down of the semiconductor device, the defects of the semiconductor device during dicing are more and more seriously.

Hence, for improving the electron mobility of the semiconductor device and raising the yield of the semiconductor device, it is an important object to provide a semiconductor structure for increasing the electron migration rate and decreasing the damage of the semiconductor device during dicing.

### SUMMARY OF THE INVENTION

In accordance with the present invention, a semiconductor structure is provided for decreasing the damage of the semiconductor device during dicing by employing a substrate with a crystal direction, wherein the crystal direction is favorable to the dicing of the semiconductor structure, so that the yield of the semiconductor device can be improved.

It is another object of this invention to improve the performance of the semiconductor device by utilizing a substrate with a crystal direction favorable to electron migration.

In accordance with the above-mentioned objects, the invention provides a semiconductor structure at least comprises a first substrate, an insulator layer on the first substrate, and a second substrate on the insulator layer. The semiconductor structure may further comprise at least one semiconductor device formed on the second substrate. The crystal directions of the first substrate and the second substrate are respectively in a first direction and a second direction. The first direction is favorable for dicing the semiconductor structure into chips, and thus the damage of the semiconductor device during the dicing process can be efficiently reduced. The second direction is favorable to favorable to the electron migration of the semiconductor device, and the electron carrier mobility of the semiconductor can be efficiently improved. Therefore, the design of this prevent invention can efficiently improve the yield and the performance of the semiconductor device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a diagram showing a semiconductor structure according to this presented invention; and

FIG. 2A to FIG. 2C depict the formation of a semiconductor structure according to this presented invention.

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Then, the components of the semiconductor devices are not shown to scale. Some dimensions are exaggerated to the related components to provide a more clear description and comprehension of the present invention.

According to the study, the crystal direction is related with the character of the semiconductor structure. For example, when the crystal direction of the substrate is in some direction, the semiconductor structure will have better cleavage and break cleaner along scribe lines, so that the chips do not fracture during dicing. Additionally, when the crystal direction of the substrate is in some direction, the mobility of the carriers will be raised. In this invention, a semiconductor structure comprising both of the above-mentioned features is disclosed, so that the yield and the performance of the semiconductor device will be improved.

One preferred embodiment of this invention is a semiconductor structure. The semiconductor structure of this embodiment comprises a first substrate, an insulator layer on the first substrate, and a second substrate on the insulator layer. The crystal direction of the first substrate is in a first direction, and the crystal direction of the second substrate is in a second direction.

In this present embodiment, the first direction of the first substrate is favorable for dicing the semiconductor structure into chips. That is, according to this embodiment, the first substrate with the first crystal direction has better cleavage and breaks cleaner alone scribe lines, so that the semiconductor device do not fracture during dicing the semiconductor structure into chips. Additionally, the second crystal direction of the second substrate is favorable for raising the electron carrier mobility of the semiconductor device on the second substrate, such as the MOSFET. Hence, according to this embodiment, not only the damages of the semiconductor device during the dicing can be reduced, but also the electron carrier mobility of the semiconductor device can be raised. Therefore, the yield and the performance of the semiconductor device can be efficiently improved by the design of this embodiment.

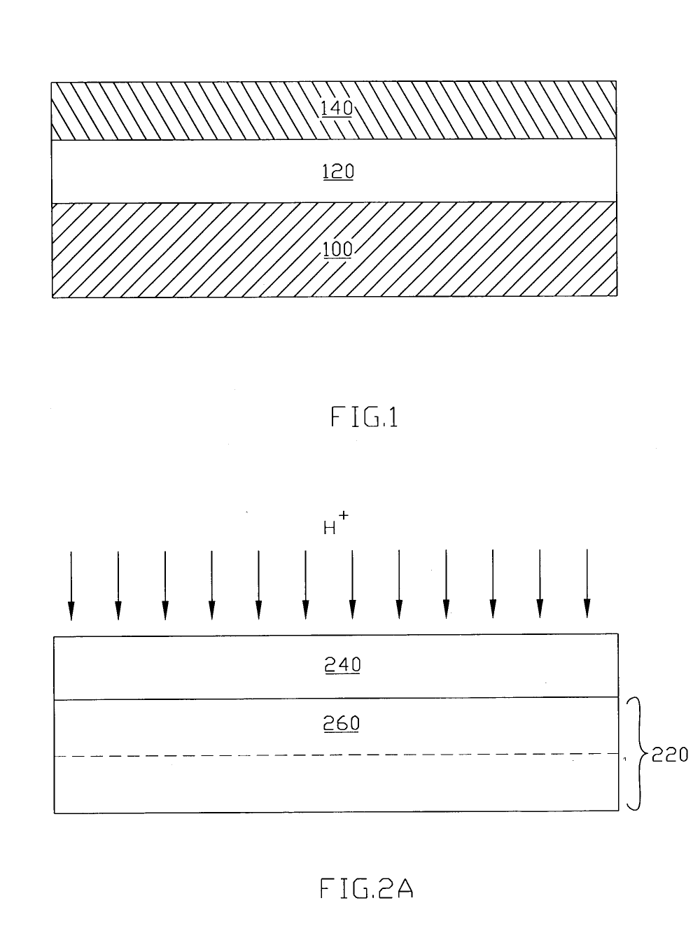

Another preferred embodiment of this present invention is a semiconductor structure. The above-mentioned semiconductor structure may comprise silicon on insulator (SOI) structure. FIG. 1 depicts a semiconductor structure according to this embodiment. Referring to FIG. 1, the semiconductor structure comprises a first substrate 100, an insulator layer 120 on the first substrate 100, and a second substrate 140 on the insulator layer 120. The first substrate 100 and the second substrate 140 comprise Si. The insulator layer 120 comprises silicon oxide.

According to this embodiment, the crystal direction of the first substrate 100 is in a first direction. The first direction is favorable for dicing the semiconductor structure into chips. In other words, when dicing the semiconductor structure of this embodiment, the semiconductor structure has better cleavage and breaks cleaner along scribe lines. According to the design of this embodiment, the chips do not fracture during dicing. In one case of this embodiment, the first direction may be <110>.

In this manner, the semiconductor structure may further comprise at least one semiconductor device on the second substrate 140, such as MOSFET or others. The crystal direction of the second substrate 140 is in a second direction. The second direction is favorable to the electron migration of the semiconductor device, so that the electron carrier mobility of the semiconductor device can be raised. Therefore, according to this embodiment, the performance of the semiconductor device can be improved.

According to this embodiment, the second substrate 140 can be formed on the first substrate 100 by a wafer bonding technology. The second substrate 140 may be rotated in an angle related to the first substrate 100, and then bonded on the first substrate 100. In one case of this embodiment, the crystal direction of the first substrate 100 is in <110>, and the crystal direction of the second substrate 140 is in <100>. In this case, the second substrate 140 can be bonded on the first substrate 100 by the wafer bonding technology without any rotation. That is, in the above-mentioned case, the rotating angle of the second substrate 140 before bonding on the first substrate 100 is 0 degree.

In another case of this embodiment, the crystal directions of the first substrate 100 and the second substrate 140 are both in <100>. In this case, in order to comprise the features of reducing the fracture of the chips during dicing and improving the electron carrier mobility of the semiconductor device, the second substrate 140 can be rotated in about 45 degree and then bonded on the first substrate 100. Therefore, in the semiconductor structure of this case, the crystal direction of the first substrate 100 is favorable for dicing the semiconductor structure into chips, and the crystal direction of the second substrate 140 is favorable to the electron carrier mobility of the semiconductor device.

According to this embodiment, because the crystal direction of the first substrate 100 is favorable for dicing the semiconductor structure, the semiconductor structure will break cleaner along scribe lines and the chips of this embodiment do not fracture or get damages during dicing the semiconductor structure into chips. On the other hand, because the crystal direction of the second substrate 140 is favorable to the electron migration, the electron carrier mobility of the semiconductor device will be raised. Hence, according to this embodiment, the yield and the performance of the semiconductor device can be efficiently improved.

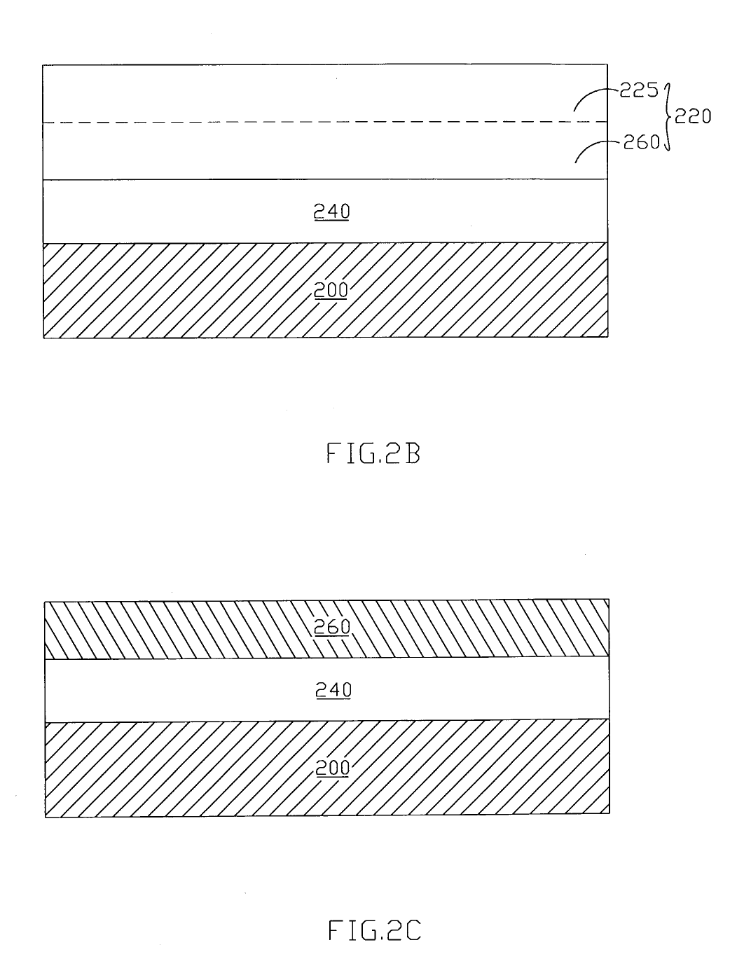

In order to explain this present invention more detailed, another preferred embodiment of this present invention is the formation of a semiconductor structure. The formation is employed only for explaining this invention, and this invention should not be limited by the following description. The above-mentioned semiconductor structure may comprise a bonding and etch-back silicon on insulator (BESOI) structure. FIG. 2A to FIG. 2C show the formation of the semiconductor structure of this embodiment.

First of all, a first substrate 200 and a second substrate 220 are provided. Referring to FIG. 2A, a silicon oxide layer 240 is formed on the second substrate 220, and an ion implanting is performed on one side of the second substrate 220. The ion employed in the ion implanting comprises hydrogen ion (H⁺). The ion implanting region in the second substrate 220 is marked as 260 in FIG. 2A.

Subsequently, the second substrate 220 can be bonded to the first substrate 200 with the ion-implanted side of the second substrate 220 by a wafer bonding technology. The wafer bonding technology comprises a process performed at a high temperature. In this manner, a semiconductor structure comprising the first substrate 200—silicon oxide layer 240—second substrate 220 SOI structure is formed, as shown in FIG. 2B.

Before bonding the second substrate 220 to the first substrate 200, the second substrate 220 may be rotated in an angle. For example, in one case of this embodiment, the crystal directions of the first substrate 200 and the second substrate 220 are both in <110>. In this case, the second substrate 220 can be rotated in 45 degree and then bonded to the first substrate 200. Therefore, in the SOI structure of this case, the crystal direction of the first substrate 200 is favorable for dicing the semiconductor structure into chips, and the crystal direction of the second substrate 220 is favorable to the electron migration.

In another case of this embodiment, the crystal direction of the first substrate 200 is in <110>, and the crystal direction of the second substrate 220 is in <100>. In this case, the second substrate 220 can be rotated 0 degree and bonded to the first substrate 200. In other words, the second substrate 220 can be directly bonded to the first substrate 200 with the ion-implanted side.

Next, portion of the second substrate 220 is removed by a smart cut technology. Under a high temperature treatment, the region without ion implantation of the second substrate 220, marked as 225 in FIG. 2B, is removed. The above-mentioned smart cut process at least comprises a high temperature treatment for removing the non-ion implantation region 225, and a chemical mechanical polishing (CMP) treatment for leveling the topmost of the second substrate 220. After the smart cut process, the non-implantation region 225 of the second substrate 220 is removed, and a semiconductor structure with SOI as shown in FIG. 2C is formed. The non-implantation region 225 of the second substrate 220 can be recycled and employed as the first substrate 200 or the second substrate 220 at the next time.

In the semiconductor structure of the prior art, in order to keep the semiconductor device from the fracture or damage during dicing, the semiconductor device is formed on a substrate with the crystal direction favorable for dicing the semiconductor structure into chips. For example, the crystal direction of the above-mentioned substrate is <110>. However, the above-mentioned crystal direction is not favorable to the electron migration, and the electron carrier mobility of the semiconductor device will be decreased by the substrate.

With the development of the manufacture, in another semiconductor structure of the prior art, in order to improve the electron carrier mobility, the semiconductor device can be formed on the substrate with the crystal direction favorable to the electron migration, such as <100>. In this manner, the electron carrier mobility in the substrate can be raised, and the performance of the semiconductor device can be efficiently improved. However, the crystal direction of the above-mentioned substrate is not favorable for dicing. When dicing the semiconductor structure into chips, the semiconductor device will get damage or fracture, and the yield of the semiconductor device is decreased.

Comparing with the above-mentioned semiconductor structures in the prior art, this invention provides a semiconductor structure comprising two substrates with two crystal directions. The above-mentioned semiconductor structure may further comprise a SOI structure. The crystal direction of one substrate of the semiconductor structure is favorable for dicing the semiconductor structure into chips, and the crystal direction of another substrate of the semiconductor structure is favorable to the electron migration. Therefore, according to the design of this invention, the electron carrier mobility of this prevent invention is higher than the electron carrier mobility in the prior art. Moreover, the semiconductor structure of this invention has better cleavage than the semiconductor structure in the prior art, and breaks cleaner along scribe lines so that the chips do not fracture during dicing. In one preferred case of this invention, the mobility of the carriers in the substrate of this invention is higher than the mobility of the carriers in the prior art by about 70-80%. Hence, according to this invention, the fracture and damage of the semiconductor device during dicing can be reduced, and the electron carrier mobility of the semiconductor device can be increased. That is, this invention can efficiently improve the yield and the performance of the semiconductor device.

According to the preferred embodiments, this invention discloses a semiconductor structure with SOI. In this present invention, the semiconductor structure comprises a first substrate, an insulator layer on the first substrate, and a second substrate on the insulator layer. The semiconductor structure may further comprise at least one semiconductor device on the second substrate. The crystal direction of the first substrate is favorable for dicing the semiconductor structure into chips. The crystal direction of the second substrate is favorable to the electron carrier mobility. The second substrate may be formed on the first substrate by a wafer bonding technology. Before bonding to the first substrate, the second substrate may be rotated in an angle. According to this invention, the fracture of the semiconductor device during dicing can be reduced, and the electron carrier mobility of the semiconductor device can be raised. Therefore, the semiconductor structure according to this present invention can efficiently improve the yield and the performance of the semiconductor device.

Although specific embodiments have been illustrated and described, it will be obvious to those skilled in the art that various modifications may be made without departing from what is intended to be limited solely by the appended claims.

1. A semiconductor structure, comprising:
a first single crystal silicon substrate with notch oriented along a first crystal direction, wherein said first crystal direction is <110>;
an insulator layer on said first single crystal silicon substrate; and
a second single crystal silicon substrate with a second crystal direction on said insulator layer, wherein said second crystal direction increases the mobility of electrons in the semiconductor structure.

2. (Cancelled)

3. The structure according to claim 1, wherein said second crystal direction is <100>.

4. The structure according to claim 1, wherein said second crystal direction is <110>.

5. The structure according to claim 4, wherein said second single crystal silicon substrate has a rotated angle to said first single crystal silicon substrate.

6. (Cancelled)

7. A semiconductor structure, comprising:
a first single crystal silicon substrate with notch oriented along a first crystal direction, wherein said first crystal direction is <110>;
an insulator layer on said first single crystal silicon substrate; and
a second single crystal silicon substrate with a second crystal direction on said insulator layer, wherein said second single crystal silicon substrate has a rotated angle to said first single crystal silicon substrate and said second crystal direction increases the mobility of electrons in the semiconductor structure.

8-9. (Cancelled)

10. The structure according to claim 7, wherein said second crystal direction is in <100>.

11. The structure according to claim 10, wherein said rotated angle is 0 degree.

12. The structure according to claim 7, wherein said second crystal direction is in <110>.

13. The structure according to claim 12, wherein said rotated angle is 45 degree.

14. The structure according to claim 7, wherein said insulator layer comprises silicon oxide.

15. A semiconductor structure, wherein said semiconductor structure comprises a bonding and etch-back silicon on insulator structure, comprising:
a first single crystal silicon substrate with notch oriented along a first crystal direction, wherein said first crystal direction is in <110>;
a silicon oxide layer on said first single crystal silicon substrate; and
a second single crystal silicon substrate on said silicon oxide layer, wherein said second silicon substrate has a rotated angle to said first single crystal silicon substrate.

16. The structure according to claim 15, wherein said second crystal single silicon substrate comprises a second crystal direction, in <100>.

17. The structure according to claim 16, wherein said rotated angle is 0 degree.

18. The structure according to claim 15, wherein said second single crystal silicon substrate comprises a second crystal direction in <110>.

19. The structure according to claim 18, wherein said rotated angle is 45 degree.
